(19) United States
(12) Patent Application Publication
(10) Pub. No.: US 2025/0116010 A1
(43) Pub. Date: Apr. 10, 2025

(54) POLYMER FILMS

(71) Applicant: UNIVERSITY OF LIMERICK, Limerick (IE)

(72) Inventors: Micheal D. SCANLON, Limerick (IE); Alonso GAMERO-QUIJANO, Limerick (IE); Rob LEHANE, Limerick (IE); Nataly REY-MUNOZ

(21) Appl. No.: 18/687,120

(22) PCT Filed: Aug. 26, 2022
(86) PCT No.: PCT/EP2022/073804

§ 371 Date: Feb. 27, 2024

(30) Foreign Application Priority Data
Aug. 27, 2021 (GB) 2112292.4

(51) Int. Cl. C25B 3/29; C08G 61/12; C25B 3/05; C25B 3/07; C25B 3/23

(52) U.S. Cl. CPC C25B 3/29; C08G 61/126; C25B 3/05; C25B 3/07; C25B 3/23; C08G 2261/3223

(57) ABSTRACT

A method of manufacturing a polymer film, the method comprising the steps of: (i) providing an aqueous electrolyte solution comprising water and a hydrophilic electrolyte; (ii) providing an organic electrolyte solution comprising an organic solvent and a lipophilic electrolyte; (iii) contacting the aqueous electrolyte solution with the organic electrolyte solution to form an interface between the aqueous electrolyte solution and the organic electrolyte solution; and (iv) electrochemically polarising the interface to oxidise the monomer, thereby forming a polymer film; wherein one of the aqueous electrolyte solution and the organic electrolyte solution comprises an oxidant; the other of the aqueous electrolyte solution and the organic electrolyte solution comprises a monomer; the aqueous electrolyte solution and the organic electrolyte solution are immiscible; and the concentration of the monomer is equal to or greater than the concentration of the oxidant.

The present invention relates to methods of manufacturing polymer films, in particular conducting polymer films. The present invention also relates to polymer films.

Conducting polymers (CPs) are a class of materials capable of displaying both semiconducting and metallic behaviour. These materials find applications in energy conversion and storage, sensor, optoelectronic, photovoltaic, bioelectronic and biomedical technologies. The lightweight, flexible, and transparent nature of CPs makes them ideal for incorporation into technologies as thin films.

Conducting polymers are well known and can be made from a variety of materials. Common conducting polymers include poly(3,4-ethylenedioxythiophene) (PEDOT) and poly(3-hexylthiophene) (P3HT).

Several methods of producing CP thin films are known, including various chemical polymerisation methods, electropolymerisation methods and vapour phase techniques. Chemical polymerisation methods often involve a multistep process including the synthesis and isolation of CPs, mixing them with additives or binders, and then compressing or coating into films (spray/spin coating or inkjet/screen printing of CP solutions). However, these multistep procedures can lead to low material utilisation and increase the risk of detachment of additives during long-term usage, jeopardising thin film lifespan. Furthermore, many chemical film processing methods are not suitable for technologically ubiquitous hydrophobic CPs, such as poly(3,4-ethylenedioxythiophene) (PEDOT). A complex of the CP and a hydrophilic surfactant additive, such as anionic poly(styrenesulfonate) (PSS), is essential to aid processability. However, an excess of PSS has detrimental effects on CP thin film conductivity, long-term stability, specific capacity, and biocompatibility.

Electropolymerisation is a single-step method, producing CP thin films by oxidising monomers in solution at the electrolyte-electrode interface. Electrochemical techniques, such as cyclic voltammetry (CV) and chronoamperometry, allow the polymerisation process to be investigated. However, electrosynthesis is limited to deposition onto conducting surfaces, and less easily adapted to the synthesis of composite materials. In addition, surface defects on the electrode surface and ‘edge effects’ make the electrosynthesis of uniform large area CP thin films difficult.

Vapour phase techniques provide another single-step method, capable of producing CP thin films with high electrical conductivity and carrier mobilities by inducing a crystallite-configuration transition. However, vapour phase techniques require high vacuum and/or high temperatures, can be complicated or expensive to implement, and incompatible with heat sensitive substrates.

It is an aim of the present invention to provide a method of manufacturing polymer films that addresses at least one disadvantage of the prior art, whether identified here or elsewhere, or to provide an alternative to existing methods.

According to a first aspect of the present invention, there is provided a method of manufacturing a polymer film, the method comprising the steps of:
(i) providing an aqueous electrolyte solution comprising water and a hydrophilic electrolyte;
(ii) providing an organic electrolyte solution comprising an organic solvent and a lipophilic electrolyte;
(iii) contacting the aqueous electrolyte solution with the organic electrolyte solution to form an interface between the aqueous electrolyte solution and the organic electrolyte solution; and
(iv) electrochemically polarising the interface to oxidise the monomer, thereby forming a polymer film;
   wherein one of the aqueous electrolyte solution and the organic electrolyte solution comprises an oxidant; the other of the aqueous electrolyte solution and the organic electrolyte solution comprises a monomer; the aqueous electrolyte solution and the organic electrolyte solution are immiscible; and the concentration of the monomer is equal to or greater than the concentration of the oxidant.

The optional features set out herein may be used either individually or in combination with each other where appropriate and particularly in the combinations as set out in the accompanying claims. The optional features for each aspect or exemplary embodiment of the invention as set out herein are also to be read as applicable to any other aspect or exemplary embodiments of the invention, where appropriate. In other words, the skilled person reading this specification should consider the optional features for each exemplary embodiment of the invention as interchangeable and combinable between different exemplary embodiments.

The present invention relates to a method of manufacturing a polymer film. By polymer film we mean to refer to a sheet or layer of polymer. Suitably the polymer film is flexible. The polymer film suitably has a thickness of up to 1,000 μm, such as up to 5 μm, for example up to 1 μm. The polymer film suitably has a thickness of at least 5 nm, such as at least 50 nm, for example at least 100 nm. The polymer film may have a thickness of from 5 nm to 1,000 μm, such as from 50 nm to 5 μm, for example from 100 nm to 1 μm.

The polymer film may be a two-dimensional film. By “two-dimensional film” we mean to refer to a film in which both major surfaces are flat at a scale of 300 nm, i.e. free of protrusions or recesses having a length of greater than 300 nm. Suitably the two-dimensional film has a thickness of from 5 to 100 nm, such as from 20 to 80 nm, for example from 30 to 60 nm.

Step (i) of the method of the first aspect involves providing an aqueous electrolyte solution.

The aqueous electrolyte solution comprises water.

The water (prior to mixing with other components of the aqueous electrolyte solution) is suitably deionised water. The deionised water may have a resistivity of at least 10 MΩ·m, such as at least 14 MΩ·cm, for example at least 18 MΩ·cm at 25° C. For the avoidance of doubt, the aqueous electrolyte solution does not have the same conductivity or resistivity as the water alone due to the presence of, among other things, the hydrophilic electrolyte.

The aqueous electrolyte solution comprises a hydrophilic electrolyte.

In this specification, by “hydrophilic electrolyte” we mean to refer to an electrolyte which is soluble in water. The hydrophilic electrolyte suitably has a solubility of at least 10 g/L, such as at least 100 g/L in water. Suitably, the hydrophilic electrolyte is insoluble in the organic solvent. The hydrophilic electrolyte suitably has a solubility of less than 10 g/L, such as less than 1 g/L in the organic solvent.

Any suitable hydrophilic electrolyte may be used. Suitable hydrophilic electrolytes will be known to the person skilled in the art. The hydrophilic electrolyte may be inorganic. The hydrophilic electrolyte suitably comprises a cation and an anion. The cation may be selected from hydrogen, ammonium, an alkali metal, an alkaline earth metal, or a mixture thereof. Suitable alkali earth metals include lithium, sodium, potassium, or a mixture thereof. Suitable alkaline earth metals include calcium, magnesium, or a mixture thereof. The anion may be selected from a halide, an oxyanion or a mixture thereof. Suitable halides include fluoride, chloride, iodide, or a mixture thereof. Suitable oxyanions include nitrate, phosphate, sulfate, methanesulfonate, chlorate, perchlorate or a mixture thereof. Particularly suitable hydrophilic electrolytes include methanesulfonic acid, sulfuric acid and perchloric acid.

The concentration of the hydrophilic electrolyte in the aqueous electrolyte solution is suitably from 0.005 to 1.0 M, such as from 0.01 to 0.8 M, for example from 0.10 to 0.6 M. The concentration of the hydrophilic electrolyte described herein suitably refers to the total concentration of all hydrophilic electrolytes present in the aqueous electrolyte solution. The unit “M” used herein in relation to concentrations is equivalent to “mol/dm3”.

Step (ii) of the method of the first aspect involves providing an organic electrolyte solution.

Step (i) and step (ii) may be carried out in any order.

The organic electrolyte solution comprises an organic solvent.

The organic solvent is preferably immiscible with water. By “immiscible” we mean that the organic solvent does not form a homogeneous mixture when mixed with water at a temperature of 25° C. and a pressure of 100 kPa. The organic solvent is suitably insoluble in water. Suitably, the organic solvent has a solubility of less than 10 g/L, such as less than 1 g/L in water.

Any suitable organic solvent may be used. Suitable organic solvents will be known to the person skilled in the art. The organic solvent is suitably polarisable. The density of the organic solvent may be higher or lower than the density of water. Preferably the organic solvent has a higher density than water. Preferred organic solvents are halogenated solvents, aromatic solvents, ketones and nitriles. Suitable organic solvents include toluene, chloroform, 5-nonanone, 2-heptanone, butyronitrile, 1,2-dichloroethane, 1,2-dichlorobenzene, nitrobenzene, and α,α,α-trifluorotoluene. Preferably the organic solvent comprises α,α,α-trifluorotoluene.

The organic electrolyte solution comprises a lipophilic electrolyte.

The lipophilic electrolyte is preferably soluble in the organic solvent. The lipophilic electrolyte suitably has a solubility of at least 10 g/L, such as at least 100 g/L in the organic solvent. Suitably, the lipophilic electrolyte is insoluble in water. The lipophilic electrolyte suitably has a solubility of less than 10 g/L, such as less than 1 g/L in water.

Any suitable lipophilic electrolyte may be used. Suitable lipophilic electrolytes will be known to the person skilled in the art. The lipophilic electrolyte suitably comprises a cation and an anion. The cation and/or the anion may comprise an organic group. Suitably the cation and the anion both comprise an organic group. By “organic group” we mean to refer to a group of atoms containing covalently bonded carbon atoms. The organic group may comprise an optionally substituted alkyl, alkenyl or aryl group. The organic group suitably comprises an optionally substituted aryl group. For example, the organic group may comprise an unsubstituted phenyl group and/or a phenyl group substituted with one or more halogen atoms, such as fluorine, chlorine, or bromine. The substituted phenyl group may comprise a pentafluorophenyl group.

The cation suitably comprises a nitrogen atom and/or a phosphorus atom. The cation may comprise an ammonium cation, such as a quaternary ammonium cation. The nitrogen atom and/or the phosphorus atom may be substituted with the organic group. Suitable cations include tetrabutylammonium, tetraphenylammonium, and bis(triphenylphosphoranylidene)ammonium. The anion suitably comprises a boron atom. The anion may comprise a borate anion. The boron atom may be substituted with the organic group. Suitable anions include tetraki(4-chlorophenyl)borate and tetrakis(pentafluorophenyl)borate. A particularly suitable lipophilic electrolyte is bis(triphenylphosphoranylidene)ammonium tetrakis(pentafluorophenyl)borate (BATB).

The concentration of the lipophilic electrolyte in the organic electrolyte solution is suitably from 1 to 50 mM, such as from 2 to 25 mM, for example from 3 to 10 mM. The concentration of the lipophilic electrolyte described herein suitably refers to the total concentration of all lipophilic electrolytes present in the organic electrolyte solution.

One of the aqueous electrolyte solution and the organic electrolyte solution comprises an oxidant and the other of the aqueous electrolyte solution and the organic electrolyte solution comprises a monomer. By this we mean that the aqueous electrolyte solution and the organic electrolyte solution each contain either an oxidant or a monomer. Preferably, the aqueous electrolyte solution comprises the oxidant and the organic electrolyte solution comprises the monomer.

The organic electrolyte solution or the aqueous electrolyte solution comprises an oxidant. The oxidant may also be known in the art as an oxidising agent. Any suitable oxidant may be used. Suitable oxidants will be known to a person skilled in the art.

When the aqueous electrolyte solution comprises the oxidant, the oxidant preferably comprises a hydrophilic oxidant. The hydrophilic oxidant is preferably insoluble in the organic solvent. The hydrophilic oxidant suitably has a solubility of less than 10 g/L, such as less than 1 g/L in the organic solvent. The hydrophilic oxidant is preferably soluble in water. The hydrophilic oxidant suitably has a solubility of at least 10 g/L, such as at least 100 g/L in water.

The hydrophilic oxidant may comprise a metal-free oxidant and/or a metal-containing oxidant. The hydrophilic oxidant may be inorganic. The metal-free oxidant may comprise hydrogen peroxide. The hydrophilic oxidant may comprise Fenton's reagent (a solution of hydrogen peroxide and an iron (II) compound, such as iron (II) sulfate). The metal-containing oxidant suitably comprises a transition metal, such as chromium, manganese, iron, iridium, gold, cerium, or a mixture thereof. Suitably the transition metal is present as a cation. The metal-containing oxidant may comprise an anion, such as a halide, an oxyanion or a mixture thereof. Suitable halides include fluoride, chloride, iodide, or a mixture thereof. Suitable oxyanions include nitrate, phosphate, sulfate, chlorate, perchlorate or a mixture thereof. The oxidant suitably comprises a cerium compound, such as a cerium (IV) compound. Particularly suitable cerium compounds include ceric ammonium nitrate and cerium (IV) sulfate.

When the organic electrolyte solution comprises the oxidant, the oxidant preferably comprises a lipophilic oxidant. The lipophilic oxidant is preferably insoluble in water. The lipophilic oxidant suitably has a solubility of less than 10 g/L, such as less than 1 g/L in water. The lipophilic oxidant is preferably soluble in the organic solvent. The lipophilic oxidant suitably has a solubility of at least 10 g/L, such as at least 100 g/L in the organic solvent.

The lipophilic oxidant may be organic. The lipophilic oxidant may be free of hydrogen atoms. Suitable lipophilic oxidants include aromatic oxidants and polyunsaturated oxidants. By polyunsaturated oxidants we mean to refer to oxidants containing two or more carbon-carbon double bonds. The aromatic oxidant may comprise an aromatic peroxide compound. The polyunsaturated oxidant may comprise cyclic or polycyclic groups. The aromatic oxidant or polyunsaturated oxidant may comprise halo and/or cyano groups. Examples of lipophilic include oxidants benzoyl peroxide, methyltriphenylphosphonium peroxodisulfate, 2,3-dichloro-5,6-dicyano-p-benzoquinone (DDQ), and halobenzoquinones (such as p-fluoranil, o- and p-chloranil and o-bromanil).

Preferably, the concentration of the oxidant in the aqueous electrolyte solution or the organic electrolyte solution is up to 70 mM, for example up to 50 mM. The concentration of the oxidant in the aqueous electrolyte solution or the organic electrolyte solution is suitably up to 20 mM, such as up to 10 mM, for example up to 5 mM. The concentration of the oxidant in the aqueous electrolyte solution or the organic electrolyte solution may be at least 0.1 mM, suitably at least 0.5 mM, such as at least 1.0 mM, for example at least 1.5 mM. The concentration of the oxidant in the aqueous electrolyte solution or the organic electrolyte solution may be from 0.1 to 50 mM, suitably from 0.5 to 20 mM, such as from 1 to 10 mM, for example from 1.5 to 5 mM. The concentration of the oxidant described herein suitably refers to the total concentration of all oxidants present in the aqueous electrolyte solution or the organic electrolyte solution.

The organic electrolyte solution or the aqueous electrolyte solution comprises a monomer. Any suitable monomer may be used. Suitable monomers will be known to the person skilled in the art. By “monomer” we mean any compound that can react with other monomers to form a polymer. In this sense the monomer may also be taken to include oligomers. By “oligomer” we mean to refer to a polymer containing from 2 to 10, such as from 2 to 5 units derived from a monomer (which is not itself an oligomer).

In some embodiments the aqueous electrolyte solution or the organic electrolyte solution may comprise a mixture of two or more monomers. Preferably the monomer is oxidisable. Preferred monomers form a radical cation on oxidation. Such radical cations are suitably able to react with another radical cation to form a covalent bond between the cations. The monomer is suitably polymerisable so as to form a conducting polymer. The polymer film manufactured by the method of the first aspect of the present invention may be a conducting polymer film.

Suitable monomers include aromatic compounds, such as a compound comprising an aryl or heteroaryl group. The monomer suitably comprises an optionally substituted thiophene, an optionally substituted pyrrole, an optionally substituted aniline, an oligomer of an optionally substituted thiophene, an oligomer of an optionally substituted pyrrole, an oligomer of an optionally substituted aniline, or mixtures thereof.

When the organic electrolyte solution comprises the monomer, the monomer preferably comprises a lipophilic monomer. The lipophilic monomer is preferably insoluble in water. The lipophilic monomer suitably has a solubility of less than 10 g/L, such as less than 1 g/L in water. The lipophilic monomer is preferably soluble in the organic solvent. The lipophilic monomer suitably has a solubility of at least 10 g/L, such as at least 100 g/L in the organic solvent.

The lipophilic monomer suitably comprises an optionally substituted thiophene, a substituted pyrrole, a substituted aniline, an oligomer of an optionally substituted thiophene, an oligomer of an optionally substituted pyrrole, an oligomer of an optionally substituted aniline, or mixtures thereof. Preferably the lipophilic monomer comprises an optionally substituted thiophene, an oligomer of an optionally substituted thiophene, or a mixture thereof.

The optionally substituted thiophene may comprise unsubstituted thiophene and/or a substituted thiophene. The substituted thiophene may comprise a 3-alkylthiophene and/or a 3,4-alkylenedioxythiophene. The alkyl group of the 3-alkylthiophene may have from 1 to 20 carbon atoms, such as from 4 to 16 carbon atoms, for example from 6 to 12 carbon atoms. Suitable 3-alkylthiophenes include 3-hexylthiophene, 3-octylthiophene and 3-dodecylthiophene. Suitable 3,4-alkylenedioxythiophenes include 3,4-ethylenedioxythiophene and 3,4-propylenedioxythiophene. A suitable oligomer of thiophene is 2,2′:5′,2″-terthiophene.

The substituted pyrrole may comprise a 1-alkylpyrrole or a 3-alkylpyrrole. The alkyl group of the 1-alkylpyrrole may have from 4 to 20 carbon atoms, such as from 6 to 16 carbon atoms, for example from 8 to 12 carbon atoms. The alkyl group of the 3-alkylpyrrole may have from 4 to 20 carbon atoms, such as from 6 to 16 carbon atoms, for example from 8 to 12 carbon atoms. A suitable oligomer of an optionally substituted pyrrole is terpyrrole,

The substituted aniline may comprise a 2-alkylaniline or a 3-alkylaniline. The alkyl group of the 2-alkylaniline may have from 1 to 20 carbon atoms, such as from 4 to 16 carbon atoms, for example from 6 to 12 carbon atoms. The alkyl group of the 3-alkylaniline may have from 1 to 20 carbon atoms, such as from 4 to 16 carbon atoms, for example from 6 to 12 carbon atoms.

Preferably, the lipophilic monomer comprises 3-hexylthiophene, 3,4-ethylenedioxythiophene, and/or 2,2′:5′,2″-terthiophene. In one embodiment the lipophilic monomer comprises 3,4-ethylenedioxythiophene. In another embodiment the lipophilic monomer comprises a mixture of 3-hexylthiophene and 2,2′:5′,2″-terthiophene. The molar ratio of 3-hexylthiophene to 2,2′:5′,2″-terthiophene is suitably from 500:1 to 2500:1, such as from 700:1 to 1500:1, for example from 900:1 to 1100:1.

When the aqueous electrolyte solution comprises the monomer, the monomer preferably comprises a hydrophilic monomer. The hydrophilic monomer is preferably insoluble in the organic solvent. The hydrophilic monomer suitably has a solubility of less than 10 g/L, such as less than 1 g/L in the organic solvent. The hydrophilic monomer is preferably soluble in water. The hydrophilic monomer suitably has a solubility of at least 10 g/L, such as at least 100 g/L in water.

The hydrophilic monomer suitably comprises an optionally substituted pyrrole, an optionally substituted aniline, or a mixture thereof. Preferably the hydrophilic monomer comprises unsubstituted pyrrole or unsubstituted aniline.

Preferably, the concentration of the monomer in the aqueous electrolyte solution or the organic electrolyte solution is up to 70 mM, for example up to 50 mM. The concentration of the monomer in the aqueous electrolyte solution or the organic electrolyte solution is suitably up to 45 mM, such as up to 35 mM, for example up to 30 mM. The concentration of the monomer in the aqueous electrolyte solution or the organic electrolyte solution may be at least 1 mM, suitably at least 2 mM, such as at least 3 mM, for example at least 4 mM. The concentration of the monomer in the aqueous electrolyte solution or the organic electrolyte solution may be from 1 to 50 mM, suitably from 2 to 45 mM, such as from 3 to 35 mM, for example from 4 to 30 mM. The concentration of the monomer described herein suitably refers to the total concentration of all monomers present in the aqueous electrolyte solution or the organic electrolyte solution.

The concentration of the monomer is equal to or greater than the concentration of the oxidant. The concentration of the monomer is determined based on the volume of the electrolyte solution in which the monomer is present, and the concentration of the oxidant is based on the volume of the electrolyte solution in which the monomer is present. For example, when the aqueous electrolyte solution comprises the oxidant and the organic electrolyte solution comprises the monomer, the concentration of the monomer in the organic electrolyte solution is equal to or greater than the concentration of the oxidant in the aqueous electrolyte solution. The concentration of the monomer is suitably at least 1.5 times greater, such as at least 2 times greater than the concentration of the oxidant. The concentrations of the monomer and the oxidant described herein suitably refer to the total concentration of all monomers and oxidants, respectively, present in the organic electrolyte solution or the aqueous electrolyte solution.

The oxidant and the monomer have standard redox potentials which are measured versus the standard hydrogen electrode (SHE). Methods of measuring the standard redox potential will be well known to the person skilled in the art. The standard redox potential for interfacial electron transfer is a measure of how much the electron transfer from the monomer to the oxidant through the interface between the aqueous electrolyte solution and the organic electrolyte solution can be influenced by electrochemically polarising the interface. The standard redox potential for interfacial electron transfer is suitably obtained by subtracting the standard redox potential of the oxidant from the standard redox potential of the monomer. Alternatively, the standard redox potential for interfacial electron transfer may be determined by using a closed bipolar electrochemical cell containing the aqueous electrolyte solution and the organic electrolyte solution. This is because electron transfer between redox couples in the closed bipolar electrochemical cell is thermodynamically equivalent to interfacial electron transfer. Methods of determining standard redox potentials using a closed bipolar electrochemical cell will be known to the person skilled in the art.

Suitably, the oxidant and monomer have a standard redox potential for interfacial electron transfer that is within the Galvani polarisable potential window of the interface. By Galvani polarisable potential window, we mean the extent to which the interface can be electrochemically polarised. The Galvani polarisable potential window of the interface may be from −0.4 to +0.6 V on the Galvani scale. The oxidant and monomer suitably have a standard redox potential for interfacial electron transfer from −0.4 to +0.6 V, such as from −0.2 to +0.5 V, for example from 0.0 to +0.2 V.

Where a mixture of monomers is present, different combinations of the oxidant and the monomers will have different standard redox potentials for interfacial electron transfer. Suitably, the oxidant and at least one of the monomers has a standard redox potential for interfacial electron transfer that is within the Galvani polarisable potential window of the interface, suitably from −0.4 to +0.6 V, such as from −0.2 to +0.5 V, for example from 0.0 to +0.2 V. Oxidation of at least one monomer may advantageously initiate the polymerisation of other monomers in the electrolyte solution having a higher standard redox potential.

Step (iii) of the method of the first aspect of the present invention involves contacting the aqueous electrolyte solution with the organic electrolyte solution to form an interface between the aqueous electrolyte solution and the organic electrolyte solution. Such an interface may also be known in the art as an interface between two immiscible electrolyte solutions (ITIES).

Unless otherwise specified, any reference to an interface herein refers to the interface between the aqueous electrolyte solution and the organic electrolyte solution.

The aqueous electrolyte solution and the organic electrolyte solution are immiscible. By “immiscible” we mean that the aqueous electrolyte solution and the organic electrolyte solution do not form a homogeneous mixture when mixed together at a temperature of 25° C. and a pressure of 100 kPa.

Preferably none of the components of the aqueous electrolyte solution are soluble in the organic electrolyte solution. Suitably all the components of the aqueous electrolyte solution have a solubility of less than 10 g/L, such as less than 1 g/L in the organic electrolyte solution. Preferably none of the components of the organic electrolyte solution are soluble in the aqueous electrolyte solution. Suitably all the components of the organic electrolyte solution have a solubility of less than 10 g/L, such as less than 1 g/L in the aqueous electrolyte solution.

References herein to a material being miscible, immiscible, soluble or insoluble in water or a solvent are with respect to a temperature of 25° C. and a pressure of 100 kPa (1 bar), unless otherwise specified.

The electrolyte solutions are suitably contacted without mixing the aqueous electrolyte solution with the organic electrolyte solution. This minimises the formation of any emulsion which might interfere with the polymerisation of the monomer.

The electrolyte solutions are suitably contacted by introducing the aqueous electrolyte solution and the organic electrolyte solution into a suitable container. The container may be an electrochemical cell. The electrochemical cell suitably comprises two or more electrodes. The electrolyte solutions are suitably introduced into the electrochemical cell so that at least one of the electrodes is in contact with the aqueous electrolyte solution and at least one of the electrodes is in contact with the organic electrolyte solution.

The aqueous electrolyte solution and/or the organic electrolyte solution may further comprise one or more additives. The additive may be added to the aqueous electrolyte solution in step (i), to the organic electrolyte solution in step (ii), or after formation of the interface in step (iii) of the method of the first aspect. The additive may be arranged at the interface so that a composite polymer film comprising the additive forms in step (iv). Suitable additives include carbon nanomaterials, poly(oxymetalates), metallic nanoparticles, and metal oxides. Suitable carbon nanomaterials include graphene, graphene oxide, carbon nanotubes (such as single-walled carbon nanotubes), and carbon black. Suitable metallic nanoparticles include gold, silver and platinum nanoparticles. Suitable metal oxides include TiO₂, WO₃, Fe₂O₃, ZnO, GeO₂, and RuO₂.

Preferably the aqueous electrolyte solution and the organic electrolyte solution do not comprise surfactants, such as poly(styrenesulfonate).

Step (iv) of the method of the first aspect of the present invention involves electrochemically polarising the interface (between the aqueous electrolyte solution and the organic electrolyte solution) to oxidise the monomer, thereby forming a polymer film.

Oxidation of the monomer produces a reactive monomer which is able to polymerise with other monomers. Since polymerisation occurs at the interface between the electrolyte solutions, which is two-dimensional, a polymer film is formed.

By “electrochemically polarising the interface”, we mean manipulating or controlling the interfacial Galvani potential difference, i.e. the Galvani potential difference between the aqueous electrolyte solution and the organic electrolyte solution at the interface.

Suitably, step (iv) comprises positively electrochemically polarising the interface. Suitably, the interface is electrochemically polarised so that the interfacial Galvani potential difference is more positive than the standard redox potential for interfacial electron transfer between the oxidant and the monomer. This drives the oxidation of the monomer forward. The interface may be electrochemically polarised so that the interfacial Galvani potential difference is at least +0.2 V, such as at least +0.4 V, for example at least +0.6 V. The interface is suitably polarised for a total of at least 10 seconds, such as at least 30 seconds, such as at least 1 minute, such as at least 5 minutes, such as at least 10 minutes, for example at least 20 minutes.

The interface may be electrochemically polarised electrochemically by any suitable electrochemical method. Preferred electrochemical methods involve controlling the interfacial Galvani potential difference by using a potentiostat and a suitable electrochemical cell. Suitable electrochemical cells may comprise electrodes contacting the aqueous electrolyte solution and/or the organic electrolyte solution. The electrochemical methods include potentiodynamic, galvanostatic and potentiostatic methods.

Potentiodynamic methods involve changing the interfacial Galvani potential difference over time. Suitable potentiodynamic methods include cyclic voltammetry and double potential step chronoamperometry.

The interface may be electrochemically polarised by cyclic voltammetry. This involves gradually increasing the interfacial Galvani potential difference to a maximum potential difference (i.e. positive limit) followed by gradually decreasing the interfacial Galvani potential difference to a minimum potential difference (i.e. negative limit), wherein the increase and decrease are carried out at an equal constant rate. Suitably, multiple cycles of increasing and decreasing potential differences (i.e. potential cycles) are carried out in a continuous sequence. Suitably at least 50, such as at least 100, for example at least 300 cycles are carried out.

The cyclic voltammetry may be carried out with a maximum interfacial Galvani potential difference of at least +0.2 V, such as at least +0.4 V, for example at least +0.6 V. The maximum interfacial Galvani potential difference is suitably more positive than the standard redox potential for interfacial electron transfer between the oxidant and the monomer. The cyclic voltammetry may be carried out with a minimum interfacial Galvani potential difference of up to 0 V, such as up to −0.2 V, for example up to −0.4 V.

The cyclic voltammetry is suitably carried out with a scan rate of from 5 to 100 mV/s, such as from 10 to 50 mV/s, for example from 20 to 30 mV/s. By “scan rate”, we mean the rate at which the interfacial Galvani potential difference is changed.

The interface may be electrochemically polarised by double potential step chronoamperometry. This involves applying a first interfacial Galvani potential difference (i.e. a first potential step) for a first period of time, following by applying a second interfacial Galvani potential difference (i.e. a second potential step) for a second period of time. Multiple cycles of the first and second interfacial Galvani potential differences may be applied. Suitably at least 50, such as at least 100, for example at least 300 cycles of the first and second interfacial Galvani potential differences are applied.

The first interfacial Galvani potential difference is suitably more positive than the standard redox potential for interfacial electron transfer between the oxidant and the monomer. The first interfacial Galvani potential difference is suitably at least +0.2 V, such as at least +0.4 V, for example at least +0.6 V.

The second interfacial Galvani potential difference is suitably more negative than the first Galvani potential difference. The second interfacial Galvani potential difference may be up to 0.0 V, such as up to −0.2 V, for example up to −0.4 V.

The first period of time and/or the second period of time may be from 2 to 60 seconds, such as from 5 to 30 seconds, for example from 10 to 15 seconds. The first period of time and the second period of time may be the same.

The interface may be electrochemically polarised by a galvanostatic method. This involves applying a constant current (+0.1 mA). The constant current is suitably applied for at least 5 minutes, such as at least 10 minutes, for example at least 20 minutes.

The interface may be electrochemically polarised by a potentiostatic method. This involves applying a constant interfacial Galvani potential difference (+0.1 V). The constant interfacial Galvani potential difference is suitably more positive than the standard redox potential for interfacial electron transfer between the oxidant and the monomer. The constant interfacial Galvani potential difference is suitably at least +0.2 V, such as at least +0.4 V, for example at least +0.6 V. The constant interfacial Galvani potential difference is suitably applied for at least 5 minutes, such as at least 10 minutes, for example at least 20 minutes.

Alternatively, the interface may be electrochemically polarised by adding potential-determining ions to the aqueous electrolyte solution and/or the organic electrolyte solution. When the organic electrolyte solution comprises the monomer, the potential-determining ions are suitably added to at least the organic electrolyte solution. The distribution of the potential-determining ions between the electrolyte solutions is used to control the interfacial Galvani potential difference. In particular, partitioning of the potential-determining ions across the interface electrochemically polarises the interface. The potential-determining ions are suitably added before the aqueous electrolyte solution is contacted with the organic electrolyte solution.

The potential determining ions suitably comprise a cation. Suitable cations include alkali metals and optionally substituted alkylammonium compounds. Suitable alkali metals include lithium and potassium. Suitable optionally substituted alkylammonium compounds include trimethylammonium, triethylammonium, tetramethylammonium, triethylmethylammonium, choline and thiocholine. The cation is suitably added to the aqueous electrolyte solution and/or the organic electrolyte solution in the form of a salt further comprising an anion. If the salt is added to the aqueous electrolyte solution, the anion is suitably soluble in water. For example, the anion may comprise a halide, such as chloride. If the salt is added to the organic electrolyte solution, the anion is suitably soluble in the organic solvent. For example, the anion may comprise tetrakis(pentafluorophenyl)borate.

Step (iv) may comprise stirring the electrolyte solution comprising the oxidant. The electrolyte solution comprising the oxidant is suitably stirred without causing mixing of the aqueous electrolyte solution with the organic electrolyte solution. This enhances diffusion of the oxidant to the interface.

Step (iv) is suitably carried out under ambient conditions. Step (iv) is suitably carried out under air. Step (iv) is suitably carried out at a temperature of from 15 to 30° C., such as from 20 to 25° C. Step (iv) is suitably carried out a pressure of from 90 to 110 kPa, such as at 100 kPa.

In a preferred embodiment of the method of the first aspect, the aqueous electrolyte solution comprises a hydrophilic oxidant and the organic electrolyte solution comprises a lipophilic monomer, the hydrophilic electrolyte is inorganic, the hydrophilic oxidant comprises a metal-containing oxidant, the organic solvent is polarisable, the lipophilic electrolyte comprises a cation and an anion wherein the cation and/or the anion comprises an organic group; and the monomer is polymerisable so as to form a conducting polymer.

In a preferred embodiment of the method of the first aspect, step (iv) comprises positively electrochemically polarising the interface; the aqueous electrolyte solution comprises a hydrophilic oxidant and the organic electrolyte solution comprises a lipophilic monomer, the hydrophilic electrolyte comprises a cation selected from hydrogen, ammonium, an alkali metal, an alkaline earth metal, or a mixture thereof; and an anion selected from a halide, an oxyanion or a mixture thereof; the hydrophilic oxidant comprises a cerium compound; the organic solvent comprises a halogenated solvent, an aromatic solvent, a ketone or a nitrile; the lipophilic electrolyte comprises a cation and an anion wherein the cation and the anion comprise an organic group, wherein the cation comprises a nitrogen atom and/or a phosphorus atom and the anion comprises a boron atom; and the lipophilic monomer comprises an optionally substituted thiophene, a substituted pyrrole, a substituted aniline, an oligomer of an optionally substituted thiophene, an oligomer of an optionally substituted pyrrole, an oligomer of an optionally substituted aniline, or a mixture thereof.

In a preferred embodiment of the method of the first aspect, step (iv) comprises positively electrochemically polarising the interface so that the interfacial Galvani potential difference is at least +0.2 V; the aqueous electrolyte solution comprises a hydrophilic oxidant and the organic electrolyte solution comprises a lipophilic monomer, the hydrophilic oxidant comprises a cerium (IV) compound; the organic solvent is selected from toluene, chloroform, 5-nonanone, 2-heptanone, butyronitrile, 1,2-dichloroethane, 1,2-dichlorobenzene, nitrobenzene, or α,α,α-trifluorotoluene; and the lipophilic monomer comprises an optionally substituted thiophene, an oligomer of an optionally substituted thiophene, or a mixture thereof.

In a preferred embodiment of the method of the first aspect, the aqueous electrolyte solution comprises a hydrophilic oxidant and the organic electrolyte solution comprises a lipophilic monomer; the hydrophilic oxidant is insoluble in the organic solvent; the lipophilic monomer is insoluble in water; the concentration of the hydrophilic oxidant in the aqueous electrolyte solution is up to 70 mM; and the concentration of the lipophilic monomer in the organic electrolyte solution is up to 70 mM.

In a preferred embodiment of the method of the first aspect, the aqueous electrolyte solution comprises a hydrophilic oxidant and the organic electrolyte solution comprises a lipophilic monomer; the hydrophilic oxidant is insoluble in the organic solvent; the lipophilic monomer is insoluble in water; the concentration of the hydrophilic oxidant in the aqueous electrolyte solution is from 1 to 10 mM; the concentration of the lipophilic monomer in the organic electrolyte solution is from 2 to 45 mM; and the concentration of the lipophilic monomer in the organic electrolyte solution is at least 2 times greater than the concentration of the hydrophilic oxidant in the aqueous electrolyte solution.

According to a second aspect of the present invention, there is provided a polymer film obtained by the method of the first aspect.

The polymer film may be obtainable by the method of the first aspect of the present invention.

The polymer film is suitably a conducting polymer film.

According to a third aspect of the present invention, there is provided the use of a polymer film obtained by the method of the first aspect as a conducting polymer.

The conducting polymer is suitably used to conduct electricity. The conducting polymer may be used in an electronic device. Suitable electronic devices include energy conversion and storage (ECS) devices, electronic sensors (such as organic electrochemical transistors), optoelectronic devices, photovoltaic devices, bioelectronic devices, and biomedical devices.

According to a fourth aspect of the present invention, there is provided the use of a polymer film obtained by the method of the first aspect as a substrate for growing a biological culture. The biological culture is suitably grown in vitro. Suitable biological cultures include microorganisms (such as bacteria or fungi) and cell cultures. For example, the polymer film may be used to grow a cell culture wherein the cells are derived from animals or humans.

The method of the first aspect of the present invention advantageously uses an interface between two immiscible liquids to provide a reproducible and defect-free environment for the formation of free-standing polymer films. The inventors have found that the polymerisation process can be controlled by ensuring that the aqueous electrolyte solution and organic electrolyte solution are immiscible and by careful selection of the ratio of the oxidant and monomer. Further control may be achieved by selection of the concentrations of oxidant and monomer. Since the immiscible liquids are electrolyte solutions, the oxidation of the monomer by the oxidant at the interface and hence polymerisation of the monomer can be controlled by electrochemically polarising the interface between the immiscible liquids. This method is able to provide high quality polymer films with tuneable thicknesses, morphologies and properties.

The method of the first aspect has further advantages. It is a ‘one pot’ method that does not require isolation and processing of intermediates, thereby reducing the time, energy and materials required to obtain the polymer film. The method also does not require binder or surfactant additives to enable the processing of intermediates, allowing the polymer film to be produced in a purer form having, for example, improved biocompatibility. Since the kinetics of the reaction is driven by electrochemical polarisation of the interface, rather than by the concentration of the reagents, the method allows for high material utilisation.

The method of the first aspect advantageously produces free-standing polymer films which can be easily transferred from the interface between the liquids without damage to the polymer film. Due to the ability of the interface to trap nano-and microparticles, the method is also suitable for preparing multicomponent composite films. The method is scalable, since the size and shape of the polymer film is determined by the dimensions of the container in which the method is carried out. The method can be carried out under ambient conditions, i.e. room temperature and atmospheric pressure.

The invention will now be described with reference to the following non-limiting examples.

### EXAMPLES

### Example 1

### Materials Used

All aqueous solutions were prepared with ultra-pure water (Millipore Milli-Q, specific resistivity 18.2 MΩ·cm). The organic solvent α,α,α-trifluorotoluene (TFT, 99+%) was received from Acros Organics. The organic monomer 3,4-ethylenedioxythiophene (EDOT, 97%), cerium (IV) sulfate (Ce(SO₄)₂, 99%), sulfuric acid (H₂SO₄, 95.0%), lithium chloride (LiCl, ≥99%), tetraethylammonium chloride (TEACI, 99%) and bis-(triphenylphosphoranylidene) ammonium chloride (BACl, were 97%) purchased from Sigma-Aldrich. Lithium tetrakis(pentafluorophenyl)borate diethyletherate (LiTB) was received from Boulder Scientific Company. The organic electrolyte salt bis(triphenylphosphoranylidene)ammonium tetrakis(pentafluorophenyl)borate (BATB) was prepared by metathesis of equimolar solutions of BACl and LiTB in a methanol-water (2:1 v/v) mixture. The resulting precipitates were filtered, washed and recrystallised from acetone.

### Electrolyte Solutions

An aqueous electrolyte solution was prepared containing 0.2 M H₂SO₄ electrolyte and 2 mM Ce(SO₄)₂ as the oxidant.

An organic electrolyte solution was prepared containing TFT as the organic solvent, 5 mM BATB electrolyte and 5 mM EDOT as the monomer.

### Determination of Standard Redox Potentials

Using a polycrystalline gold electrode in a three-electrode configuration, the redox potential of the Ce(SO₄)₂ in the aqueous electrolyte solution was determined as +1.430 V vs. SHE. Meanwhile, the onset potential of EDOT oxidation in the organic electrolyte solution was determined at a polycrystalline platinum electrode as +1.435 V vs. SHE. The standard redox potential for interfacial electron transfer was therefore determined to be around 0 V.

The standard redox potential for interfacial electron transfer was also confirmed to be around 0 V using a closed bipolar electrochemical cell (CBPEC). The CBPEC comprised a compartment holding the aqueous electrolyte solution and a compartment holding the organic electrolyte solution. The CBPEC comprised a bipolar electrode consisting of two individual Au disc electrodes (CH instruments, USA), one in each compartment acting as the aqueous pole (P_{w}) or organic pole (Pₒ), that were connected with an electric wire. Each compartment contained a Pt wire driving electrode and a reference electrode. The aqueous reference electrode was a Ag/AgCl (KCl gel) electrode, while the organic reference electrode was a Ag/AgCl wire immersed in an “organic reference solution” that established a liquid junction with the organic solvent. The organic reference solution was an aqueous solution of 1 mM LiCl and 10 mM BACl. The measured potential was calibrated onto the Galvani potential scale. Before use, two individual pole Au disc electrodes were polished and cleaned electrochemically in 0.2 M H₂SO₄. The organic pole was also rinsed with deionised water, acetone and TFT solvent prior to CBPEC electrochemistry. Measurements were performed in ambient conditions.

### Interfacial Electrosynthesis

Interfacial electrosynthesis was carried out at an ITIES (interface between two immiscible electrolyte solutions) formed between an acidic aqueous solution, containing 0.2 M H₂SO₄ electrolyte and 2 mM Ce(SO₄)₂ as the oxidant, and an organic TFT solution, containing 5 mM BATB electrolyte and 5 mM EDOT as the monomer. The interfacial Galvani potential difference at the electrified aqueous|TFT interface was controlled externally using an Autolab PGSTAT204 from Metrohm (Netherlands), in conjunction with NOVA software version 2.1.2. and a four-electrode electrochemical cell. The cell had the following configuration:

Ag/AgCl|BACl 1 mM, LiCl 10 mM (aq)|5 mM EDOT, 5 mM BATB in TFT∥2 mM Ce(SO₄)₂ in 0.2 M H₂SO₄|Ag/AgCl (KCl 1M)

Two reference electrodes positioned on different sides of the aqueous|TFT interface measured the potential difference across the interface. Platinum counter electrodes placed in each phase allowed the flow of electric current. The geometrical surface area of the aqueous|TFT interface was about 1.66 cm². Calibration of the voltammetry to the Galvani potential scale was achieved by assuming the formal ion transfer potential of the cation tetraethylammonium (TEA+) to be 0.149V. To enhance the diffusion of the Ce⁴⁺ oxidant in the aqueous phase, a homemade stirrer was positioned approximately 2 cm above the water|TFT interface. A glass capillary with a U-bend was used as the stirrer, which was attached to an electric motor that operated at 240 rpm.

Interfacial electrosynthesis was initiated using a double potential step chronoamperometry (DPSCA) method. The first potential step was held at an interfacial Galvani potential difference of +0.4 V for 10 s. The second potential step was then held at an interfacial Galvani potential difference of −0.1 V for 10 s. This double potential step was repeated. The electrosynthesis was carried out in ambient conditions at room temperature (21° C.).

After 50 DPSCA cycles, a blue PEDOT thin film became visible at the aqueous|TFT interface. The DPSCA cycles were repeated up to 300 times, depending on the desired thickness of the PEDOT thin film. The resulting free-standing PEDOT thin film was recovered from the interface, washed with acetone and suspended in an acetone: sulfuric acid mixture for storage.

### Example 2

The electrolyte solutions and electrochemical cell setup were the same as Example 1.

Cyclic voltammetry was used to cyclically scan the interfacial Galvani potential difference from −0.35 V to +0.5 V and back at a scan rate of 25 mV/s. After 50 potential cycles, a homogeneous thin blue PEDOT film could be seen coating the ITIES.

### Example 3

Electrochemical polymerization at a liquid-liquid interface was performed in a four-electrode cell using the following configuration:

Ag/AgCl|BACl 1 mM, LiCl 10 mM (aq)|25 mM 3HT, 25 μM 3T, 5 mM BATB in TFT|2 mM (NH₄)₂Ce(NO₃)₆ in 0.4 M HClO₄ (aq)|Ag/AgCl (KCl 1M)

The following monomers were used.
3T: 2,2′:5′,2″-Terthiophene
3HT: 3-hexylthiophene

A polymer film was synthesized by a galvanostatic method, applying currents of from 10 to 30 μA for 20 minutes. To reach these currents, the system applied an interfacial Galvani potential difference of about +0.6 to +0.65 V. After 5 minutes, a blue thin film formed at the interface between the aqueous and TFT solutions.

After the polymerisation, the aqueous solution was cleaned with HClO₄ 0.4 M and deionised water to remove the remaining cerium. The polymer film was extracted from the interface and rinsed with acetone.

After cleaning, the polymer film was transferred to a solid substrate, dried and stored in the dark and in the absence of oxygen to preserve the film from degradation.

### Example 4

### Ex Situ Conductivity

Ex situ (in-plane or dry) conductivity of a PEDOT thin film prepared by the method of Example 1 was determined with a four-strip conductivity electrode (ALS, Japan).

The current-voltage (I-V) relationship of the PEDOT thin film was measured with an Autolab PGSTAT204 potentiostat from Metrohm (Netherlands), controlled using NOVA software version 2.1.2. Ex situ conductivity measurements were performed at room temperature (21° C.) in ambient conditions. The conductivity electrode was cleaned using HPLC grade acetone and isopropanol prior to use. Once clean, the PEDOT thin film was dropcast across the four-strip conductivity electrode and oven dried at 50° C. for 2 hours. Very thin PEDOT thin films (approx. 50 nm) were used for these measurements. A linear galvanostatic sweep up to 1 mA was applied between the two outer electrodes, while the potential between the two inner electrodes was monitored. Ex situ conductivity (σ_{Ex}) was calculated using Equation S1, where w is the sample width, t is the thickness of the sample (determined by AFM), and l is the distance between the distance between the two inner electrodes.

$${σ}_{E x} = \frac{I \cdot ι}{V \cdot w \cdot t} \qquad ( S 1 )$$

The conductivity measurement was repeated for three different PEDOT thin films with the average value presented.

A value of 554 (±77) S·cm⁻¹ was determined.

Although a few preferred embodiments have been shown and described, it will be appreciated by those skilled in the art that various changes and modifications might be made without departing from the scope of the invention, as defined in the appended claims.

1. A method of manufacturing a polymer film, the method comprising the steps of:
(I) providing an aqueous electrolyte solution comprising water and a hydrophilic electrolyte;
(ii) providing an organic electrolyte solution comprising an organic solvent and a lipophilic electrolyte;
(iii) contacting the aqueous electrolyte solution with the organic electrolyte solution to form an interface between the aqueous electrolyte solution and the organic electrolyte solution; and
(iv) electrochemically polarising the interface to oxidise the monomer, thereby forming a polymer film;
wherein one of the aqueous electrolyte solution and the organic electrolyte solution comprises an oxidant; the other of the aqueous electrolyte solution and the organic electrolyte solution comprises a monomer; the aqueous electrolyte solution and the organic electrolyte solution are immiscible; and the concentration of the monomer is equal to or greater than the concentration of the oxidant.

2. The method of claim 1, wherein the aqueous electrolyte solution comprises the oxidant and the organic electrolyte solution comprises the monomer, the oxidant comprises a hydrophilic oxidant, and the monomer comprises a lipophilic monomer.

3. The method of claim 2, wherein the hydrophilic oxidant comprises a transition metal.

4. The method of claim 2, wherein the lipophilic monomer comprises an optionally substituted thiophene, a substituted pyrrole, a substituted aniline, an oligomer of an optionally substituted thiophene, an oligomer of an optionally substituted pyrrole, an oligomer of an optionally substituted aniline, or a mixture thereof.

5. The method of claim 1, wherein the monomer is polymerisable so as to form a conducting polymer.

6. The method of claim 1, wherein the concentration of the oxidant in the aqueous electrolyte solution or the organic electrolyte solution is up to 70 mM.

7. The method of claim 1, wherein the concentration of the monomer in the aqueous electrolyte solution or the organic electrolyte solution is up to 70 mM.

8. The method of claim 1, wherein the concentration of the monomer is at least 2 times greater than the concentration of the oxidant.

9. The method of claim 1, wherein the hydrophilic electrolyte is inorganic.

10. The method of claim 1, wherein the hydrophilic electrolyte comprises a cation selected from hydrogen, ammonium, an alkali metal, an alkaline earth metal, or a mixture thereof; and an anion selected from a halide, an oxyanion or a mixture thereof.

11. The method of claim 1, wherein the organic solvent is polarisable.

12. The method of claim 1, wherein the organic solvent is selected from toluene, chloroform, 5-nonanone, 2-heptanone, butyronitrile, 1,2-dichloroethane, 1,2-dichlorobenzene, nitrobenzene, or α,α,α-trifluorotoluene.

13. The method of claim 1, wherein the lipophilic electrolyte comprises a cation and an anion wherein the cation, and/or the anion, or both comprises an organic group.

14. The method of claim 13, wherein the cation comprises a nitrogen atom, a phosphorus atom, or both; and the anion comprises a boron atom.

15. The method of claim 1, wherein the oxidant and monomer have a standard redox potential for interfacial electron transfer that is from-0.4 to +0.6 V.

16. The method of claim 1, wherein step (iv) comprises positively electrochemically polarising the interface.

17. The method of claim 1, wherein the interface is electrochemically polarised so that the interfacial Galvani potential difference is more positive than the standard redox potential for interfacial electron transfer between the oxidant and the monomer.

18. The method of claim 1, wherein the interface is electrochemically polarised by using a potentiostat and an electrochemical cell comprising electrodes contacting the aqueous electrolyte solution, the organic electrolyte solution, or both.

19. A polymer film obtained by the method of claim 1.

20. (canceled)

21. (canceled)
